(19) United States
(12) Patent Application Publication
(10) Pub. No.: US 2012/0176749 A1
(43) Pub. Date: Jul. 12, 2012

(54) POWER CONVERTER AND FUEL CELL VEHICLE WITH POWER CONVERTER

(75) Inventors: Hiroshi Arisawa, Susono-shi (JP); Satoshi Oshita, Chiryu-shi (JP)

(73) Assignees: KABUSHIKI KAISHA TOYOTA JIDOSHOKKI, Toyota-shi (JP); TOYOTA JIDOSHA KABUSHIKI KAISHA, Toyota-shi (JP)

(21) Appl. No.: 13/496,464

(22) PCT Filed: Sep. 16, 2010
(86) PCT No.: PCT/IB10/02309

§ 371 Date: Mar. 15, 2012

(30) Foreign Application Priority Data
Sep. 18, 2009 (JP) 2009-216301

(51) Int. Cl. H05K 7/00

(52) U.S. Cl. 361/728

(57) ABSTRACT

A soft-switching converter includes three main reactors, three main reactor terminal blocks, three auxiliary reactors, and three auxiliary reactor terminal blocks. The main reactors and the main reactor terminal blocks are each arranged on a first line. Also, the auxiliary reactors are each arranged on a second line that is parallel to the first line. Each of the auxiliary reactor terminal blocks is arranged stacked on a corresponding one of the auxiliary reactors.

### BACKGROUND OF THE INVENTION

1. Field of the Invention

The invention relates to a power converter and a fuel cell vehicle with a power converter.

2. Description of the Related Art

Power converters have reactors. One type of power converter is a soft-switching converter. Soft-switching converters are used to step-up the output voltage of fuel cells, for example, and are mounted in fuel cell vehicles and the like.

A soft-switching converter has a main reactor and an auxiliary reactor. When forming a soft-switching converter with a drive system having a plurality of phases such as a three-phase drive system, a plurality of pairs of one main reactor and one auxiliary reactor are used.

Japanese Patent Application Publication No. 2005-57928 (JP-A-2005-57928) describes technology in which a power unit such as an inverter or a power converter is provided in a fuel cell vehicle. In order to mount the soft-switching converter of a drive system with a plurality of phases in the limited space of a fuel cell vehicle, for example, it must be compact. That is, the various components of the plurality of pairs of one main reactor and one auxiliary reactor and the like must be arranged together in a compact manner. In particular, when a soft-switching converter is mounted in a fuel cell vehicle, it often must be mounted in a relatively narrow space such as in the center console (under the floor between the driver's seat and the front passenger's seat) of the fuel cell vehicle. However, the related art does not take compactness into account.

### SUMMARY OF THE INVENTION

This invention makes a power converter having a plurality of pairs of one main reactor and one auxiliary reactor more compact.

The invention can be realized as the aspects described below.

A first aspect of the invention relates to a power converter that includes a main reactor; a main reactor terminal block having a main reactor input terminal for inputting a current into the main reactor, and a main reactor output terminal for outputting a current from the main reactor; and an auxiliary reactor that is electrically connected to the main reactor. The main reactor, the auxiliary reactor, and the main reactor terminal block are provided in a plurality of sets, and each of the plurality of main reactors and each of the plurality of main reactor terminal blocks are arranged on a first line, and each of the plurality of auxiliary reactors are arranged on a second line that is parallel to the first line.

With the power converter of this aspect, the area in which the various components that make up the power converter are arranged is smaller in the direction orthogonal to the direction in which the plurality of main reactor terminal blocks are arranged, i.e., the width direction orthogonal to the first line, than it would be if those components were to be arranged in another manner, so the power converter is able to be more compact. As a result, the power converter can be mounted in a relatively narrow space.

In the power converter described above, the main reactor input terminal and the main reactor output terminal of the main reactor terminal block may be arranged in different positions in a direction perpendicular to the mounting surface of the main reactor terminal block.

With the power converter having this structure, the input terminals and the output terminals of the main reactor terminal blocks are sterically arranged, which enables dead space to be reduced more than when they are arranged in a line on a single plane. As a result, the power converter can be made compact.

The power converter described above may also include an auxiliary reactor terminal block having an auxiliary reactor input terminal for inputting a current into the auxiliary reactor, and an auxiliary reactor output terminal for outputting a current from the auxiliary reactor. The auxiliary reactor terminal block may be provided in plurality, and each of the auxiliary reactor terminal blocks may be arranged in a position overlapping with a corresponding one of the auxiliary reactors in a direction perpendicular to the mounting surface of the auxiliary reactor.

With the power converter having this structure, the auxiliary reactor terminal blocks are arranged stacked sterically on top of the auxiliary reactors, so dead space is reduced more than when they are arranged lined up on the same plane. As a result, the power converter is able to be made compact.

The power converter described above may also include a plurality of current sensors that measure the current that flows to the plurality of main reactors, and each of the plurality of current sensors may be arranged on a third line that is parallel to the first line and on the same side of the first line as the second line.

Incidentally, in the structure described above, the second line and the third line may be different lines or they may be the same line.

The power converter described above may also include a conductive member assembly that includes the plurality of current sensors, a first conductive member that is connected to each of the plurality of auxiliary reactor input terminals, a second conductive member that is connected to each of the plurality of auxiliary reactor output terminals, and a supporting member that supports the first conductive member and the second conductive member while providing insulation between the first conductive member and the second conductive member. The conductive member assembly may be provided extending parallel to the first line, the second line, and the third line.

With the power converter having the structure described above, the conductive member assembly is provided which makes it possible to prevent an electrical short between the first conductive member and the second conductive member, and facilitate the work of connecting these to the connecting portions. Also, with the power converter having this structure, the conductive member assembly is provided extending parallel to the first, second, and third lines. Accordingly, when the first conductive member and the second conductive member are connected, the width, in a direction orthogonal to the direction in which the plurality of main reactors and the plurality of main reactor terminal blocks are arranged, of the area in which the various components that form the power converter are arranged can be suppressed from becoming larger.

Incidentally, the invention does not necessarily have to include all of the various characteristics described above, i.e., some of the characteristics may be omitted.

### BRIEF DESCRIPTION OF THE DRAWINGS

The features, advantages, and technical and industrial significance of this invention will be described in the following detailed description of example embodiments of the invention with reference to the accompanying drawings, in which like numerals denote like elements, and wherein:

FIG. 1 is a perspective view partially showing the general structure of a soft-switching converter as one example embodiment of the power converter of the invention;

FIG. 2 is a plan view of the soft-switching converter as viewed from direction z shown in FIG. 1, i.e., from a direction perpendicular to the mounting surface;

FIG. 3 is a side view of the soft-switching converter as viewed from direction x shown in FIG. 1;

FIG. 4 is a sectional view of the soft-switching converter taken along line IV-IV in FIG. 2; and

FIG. 5 is a plan view of a four-phase drive system soft-switching converter.

### DETAILED DESCRIPTION OF EMBODIMENTS

Example embodiments of the present invention will be described in greater detail below with reference to the accompanying drawings.

### A. Example Embodiments

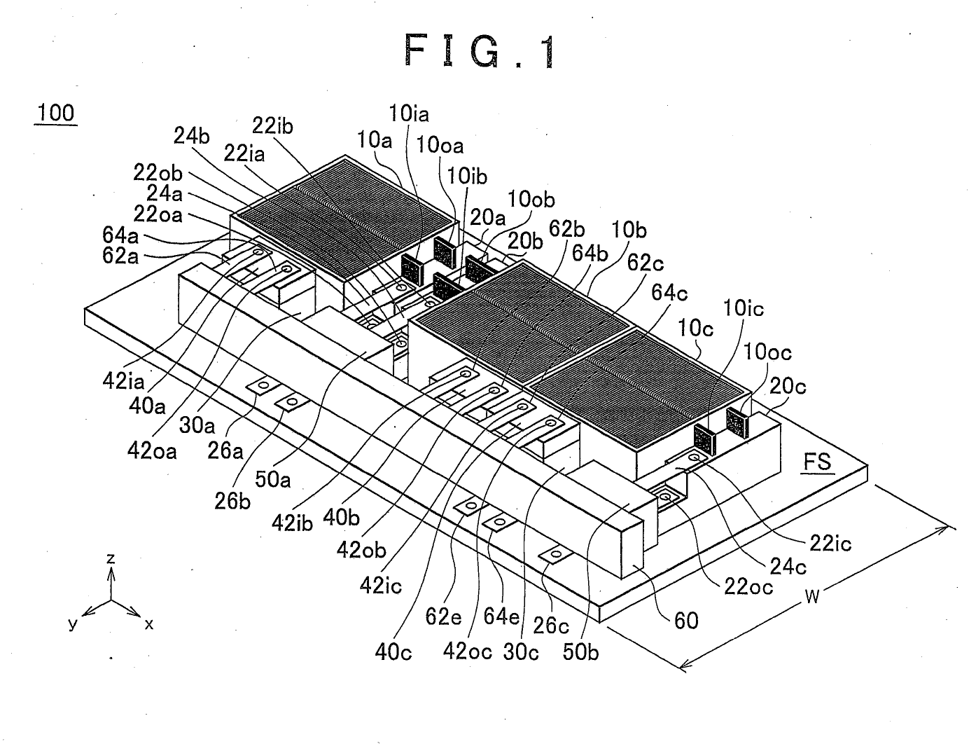

FIG. 1 is a perspective view partially showing the general structure of a soft-switching converter 100 as one example embodiment of the power converter of the invention.

The soft-switching converter 100 is a three-phase drive system soft-switching converter that has three pairs of one main reactor and one auxiliary reactor that is electrically connected to the main reactor, i.e., three main reactors 10a, 10b, and 10c, and three auxiliary reactors 30a, 30b, and 30c, provided on a mounting surface FS, as shown in the drawing. The soft-switching converter 100 also has three main reactor terminal blocks 20a, 20b, and 20c used with the three main reactors 10a, 10b, and 10c, respectively. Similarly, the soft-switching converter 100 has three auxiliary reactor terminal blocks 40a, 40b, and 40c used with the three auxiliary reactors 30a, 30b, and 30c, respectively. Incidentally, the auxiliary reactor 30b is not shown in FIG. 1 due to the nature of the drawing.

The main reactor terminal block 20a has an input terminal 22ia for inputting a current to the main reactor 10a, and an output terminal 22oa for outputting a current from the main reactor 10a. The input terminal 22ia is electrically connected to the input terminal 10ia of the main reactor 10a via a conductive member embedded in the main reactor terminal block 20a. Also, the output terminal 22oa is electrically connected to the output terminal 10oa of the main reactor 10a via a conductive member embedded in the main reactor terminal block 20a.

Similarly, the main reactor terminal block 20b has an input terminal 22ib for inputting a current to the main reactor 10b, and an output terminal 22ob for outputting a current from the main reactor 10b. The input terminal 22ib is electrically connected to the input terminal 10ib of the main reactor 10b via a conductive member embedded in the main reactor terminal block 20b. Also, the output terminal 22ob is electrically connected to the output terminal 10ob of the main reactor 10b via a conductive member embedded in the main reactor terminal block 20b.

Also, the main reactor terminal block 20c has an input terminal 22ic for inputting a current to the main reactor 10c, and an output terminal 22oc for outputting a current from the main reactor 10c. The input terminal 22ic is electrically connected to the input terminal 10ic of the main reactor 10c via a conductive member embedded in the main reactor terminal block 20c. Also, the output terminal 22oc is electrically connected to the output terminal 10oc of the main reactor 10c via a conductive member embedded in the main reactor terminal block 20c.

Further, the soft-switching converter 100 has a current sensor 50a for measuring the current that flows to the main reactors 10a and 10b, and a current sensor 50b for measuring the current that flows to the main reactor 10c. The current sensor 50a is connected to the input terminal 22ia of the main reactor terminal block 20a via a bus bar 24a, and to the input terminal 22ib of the main reactor terminal block 20b via a bus bar 24b. Similarly, the current sensor 50b is connected to the input terminal 22ic of the main reactor terminal block 20c via a bus bar 24c. Also, a bus bar 26a is connected to the outer terminal 22oa of the main reactor terminal block 20a, a bus bar 26b is connected to the output terminal 22ob of the main reactor terminal block 20b, and a bus bar 26c is connected to the output terminal 22oc of the main reactor terminal block 20c. Incidentally, the current sensor 50a measures the current that flows to both of the main reactors 10a and 10b, so it is essentially equivalent to providing a current sensor for the main reactor 10a and a current sensor for the main reactor 10b.

The auxiliary reactor terminal block 40a has an input terminal 42ia for inputting a current to the auxiliary reactor 30a, and an output terminal 42oa for outputting a current from the auxiliary reactor 30a. Similarly, the auxiliary reactor terminal block 40b has an input terminal 42ib for inputting a current to the auxiliary reactor 30b, and an output terminal 42ob for outputting a current from the auxiliary reactor 30b. Also, the auxiliary reactor terminal block 40c has an input terminal 42ic for inputting a current to the auxiliary reactor 30c, and an output terminal 42oc for outputting a current from the auxiliary reactor 30c.

Also, the soft-switching converter 100 has a bus bar assembly 60. This bus bar assembly 60 integrally supports a plurality of bus bars with an insulating support. The bus bar assembly 60 functions as a conductive member assembly of the invention.

A bus bar 62a of the bus bar assembly 60 is connected to the input terminal 42ia of the auxiliary reactor terminal block 40a, a bus bar 62b of the bus bar assembly 60 is connected to the input terminal 42ib of the auxiliary reactor terminal block 40b, and a bus bar 62c of the bus bar assembly 60 is connected to the input terminal 42ic of the auxiliary reactor terminal block 40c. Further, the bus bar assembly 60 is also connected to the current sensors 50a and 50b. Incidentally, although not shown, the bus bars 62a, 62b, and 62c of the bus bar assembly 60 are connected via a bus bar embedded in the bus bar assembly 60 to a bus bar 62e that is connected other devices.

Also, a bus bar 64a of the bus bar assembly 60 is connected to the output terminal 42oa of the auxiliary reactor terminal block 40a, a bus bar 64b of the bus bar assembly 60 is connected to the output terminal 42ob of the auxiliary reactor terminal block 40b, and a bus bar 64c of the bus bar assembly 60 is connected to the output terminal 42oc of the auxiliary reactor terminal block 40c. Incidentally, although not shown, the bus bars 64a, 64b, and 64c of the bus bar assembly 60 are integrally connected via a bus bar embedded in the bus bar assembly 60 to a bus bar 64e that is connected other devices.

The bus bars 62a, 62b, 62c, and 62e that are connected by the bus bar embedded in the bus bar assembly 60 each function as the first conductive member of the invention. Also, the bus bars 64a, 64b, 64c, and 64e that are connected by the bus bar embedded in the bus bar assembly 60 each function as the second conductive member of the invention. Further, in the bus bar assembly 60, the insulating support (the reference character for which is omitted) that integrally supports the plurality of bus bars functions as the support member of the invention.

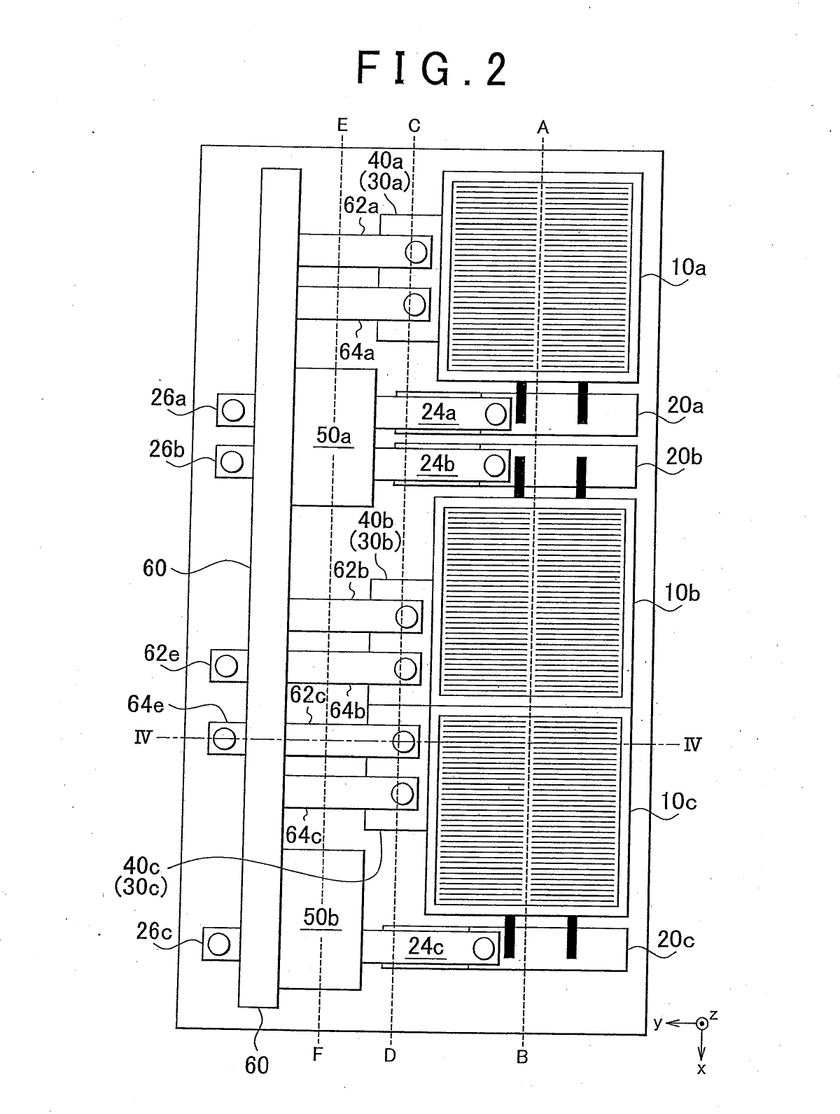

FIG. 2 is a plan view of the soft-switching converter 100 as viewed from direction z in FIG. 1, i.e., from a direction perpendicular to the mounting surface FS. As shown in the drawing, the three main reactors 10a, 10b, and 10c are arranged on line AB. Also, the three auxiliary reactors 30a, 30b, and 30c are arranged in positions adjacent to the main reactors 10a, 10b, and 10c, respectively, on a line CD that is parallel to line AB. Further, the current sensor 50a is arranged in a position adjacent to the main reactor terminal blocks 20a and 20b and the current sensor 50b is arranged in a position adjacent to the main reactor terminal block 20c, on line EF that is parallel to line AB and on the same side of line AB as line CD. Line AB functions as the first line of the invention, line CD functions as the second line of the invention, and line EF functions as the third line of the invention.

Also, the auxiliary reactor terminal blocks 40a, 40b, and 40c are arranged in positions overlapping the auxiliary reactors 30a, 30b, and 30c, respectively. That is, the auxiliary reactor terminal blocks 40a, 40b, and 40c are arranged stacked on top of the auxiliary reactors 30a, 30b, and 30c, respectively. Incidentally, as is evident from FIGS. 1 and 2, in this example embodiment, when the soft-switching converter 100 is viewed from direction z in FIG. 1, the outer shapes of the auxiliary reactor terminal blocks 40a, 40b, and 40c are generally the same as the outer shapes of the auxiliary reactors 30a, 30b, and 30c, respectively.

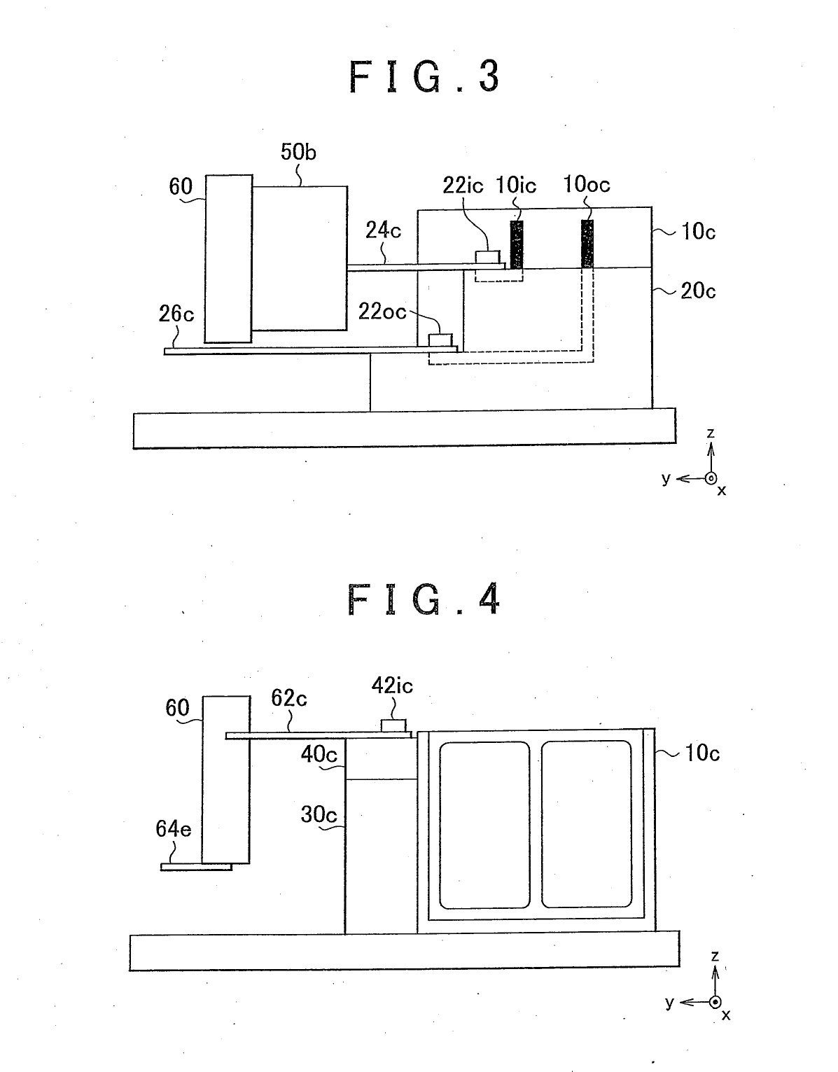

FIG. 3 is a side view of the soft-switching converter 100 as viewed from direction x in FIG. 1. As shown in the drawing, the input terminal 22ic and the output terminal 22oc of the main reactor terminal block 20c are sterically (i.e., three-dimensionally) arranged on two levels, i.e., an upper level and a lower level. That is, the input terminal 22ic and the output terminal 22oc of the main reactor terminal block 20c are arranged in different positions in a direction perpendicular to the mounting surface FS (see FIG. 1). The bus bar assembly 60, the current sensor 50b, and the bus bar 26c that is connected to the output terminal 22oc intersect three-dimensionally (see FIG. 1). The arrangement of these is the same for the main reactor terminal blocks 20a and 20b as well.

FIG. 4 is a sectional view of the soft-switching converter 100 taken along line IV-IV in FIG. 2. As shown in the drawing, the auxiliary reactor terminal block 40c is arranged stacked on top of the auxiliary reactor 30c. Incidentally, as is evident from FIG. 4, in this example embodiment, the height of the auxiliary reactor terminal block 40c when stacked on top of the auxiliary reactor 30c is substantially the same as the height of the main reactor 10c. The arrangement and height relationship of these is the same for the auxiliary reactors 30a and 30b and the auxiliary reactors 40a and 40b as well.

With the soft-switching converter 100 of this example embodiment described above, the width (denoted by reference character W in FIG. 1), in the direction perpendicular to the direction in which the three main reactors 10a, 10b, and 10c and the three main reactor terminal blocks 20a, 20b, and 20c are mounted, of the area where the various components that make up the soft-switching converter 100 are arranged (i.e., the mounting surface FS in FIG. 1), is able to be smaller than it is when these components are arranged another way, so the soft-switching converter 100 is able to be made more compact. As a result, the soft-switching converter 100 can be mounted in a relatively narrow space such as in a so-called center console of a fuel cell vehicle, for example.

Also, with the soft-switching converter 100, the input terminals 22ia, 22ib, and 22ic and the output terminals 22oa, 22ob, and 22oc of the main reactor terminal blocks 20a, 20b, and 20c, respectively, are sterically arranged, which enables dead space to be reduced more than when they are arranged in a line on a single plane. As a result, the soft-switching converter 100 can be made compact.

Also, with this soft-switching converter 100, the auxiliary reactor terminal blocks 40a, 40b, and 40c are sterically stacked on top of the auxiliary reactors 30a, 30b, and 30c; respectively, which enables dead space to be reduced more than when they are arranged in a line on a single plane. As a result, the soft-switching converter 100 can be made compact.

Further, with the soft-switching converter 100, the bus bar assembly 60 is provided extending parallel to lines AB, CD, and EF, which suppresses the width W shown in FIG. 1 from increasing.

### B. Modified Examples

While an example embodiment of the invention has been described, the invention is not in any way limited to this kind of example embodiment. To the contrary, the invention may be carried out in any one of a variety of modes within the scope of the invention. For example, the modified examples described below are also possible.

### B1. First Modified Example

In the example embodiment described above, the soft-switching converter 100 is a three-phase drive system soft-switching converter, but the invention is not limited to this. The invention may also be applied to a soft-switching converter with a drive system having a plurality of phases.

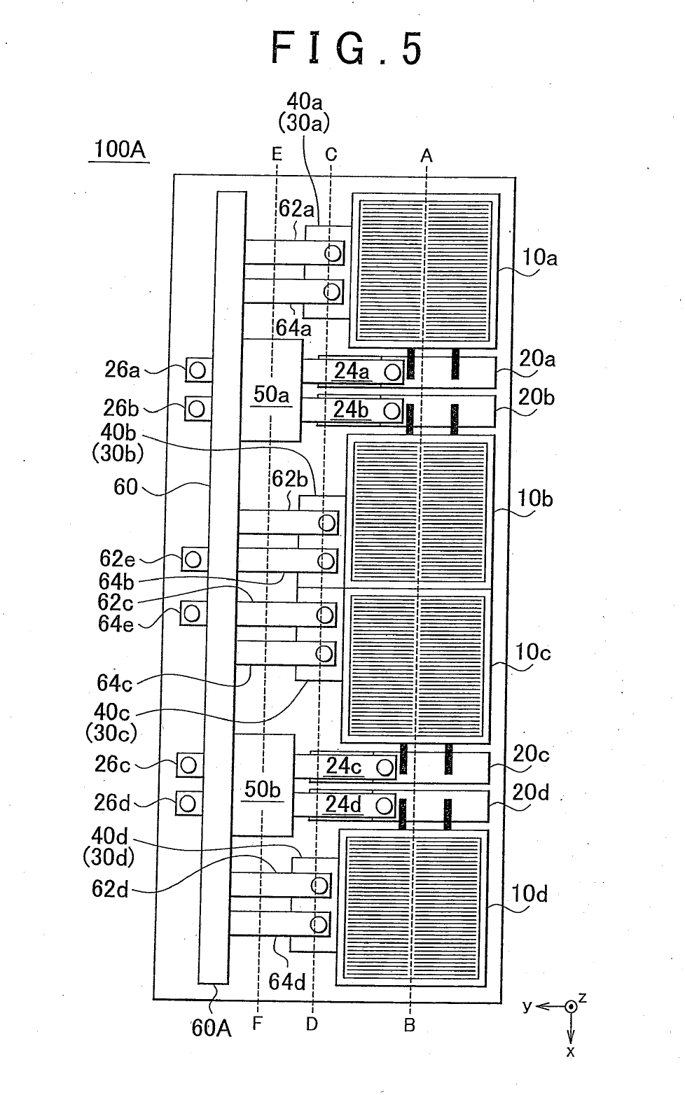

FIG. 5 is a plan view of a four-phase drive system soft-switching converter 100A. As is evident when comparing FIG. 5 with FIG. 2, in addition to the structure of the soft-switching converter 100, the soft-switching converter 100A includes a main reactor 10d, a main reactor terminal block 20d, an auxiliary reactor 30d, and an auxiliary reactor terminal block 40d and the like. The main reactor 10d and the main reactor terminal block 20d are arranged on line AB, and the auxiliary reactor 30d is arranged on line CD. The auxiliary reactor terminal block 40d is arranged stacked on top of the auxiliary reactor 30d.

Further, with the soft-switching converter 100A, a current sensor 50b is able to measure the current that flows to the two main reactors 10c and 10d. The current sensor 50b and the input terminal of the main reactor terminal block 20d are connected together by a bus bar 24d. Also, a bus bar 26d is connected to the output terminal of the main reactor terminal block 20d. Incidentally, the structure of the main reactor terminal block 20d is the same as the structures of the main reactor terminal blocks 20a, 20b, and 20c.

Further, the soft-switching converter 100A is provided with a bus bar assembly 60A instead of the bus bar assembly 60 of the soft-switching converter 100. This bus bar assembly 60A includes bus bars 62d and 64d, in addition to the structure of the bus bar assembly 60. The bus bar 62d is connected to an input terminal of the auxiliary reactor terminal block 40d. Also, the bus bar 64d is connected to an output terminal of the auxiliary reactor terminal block 40d. Further, the bus bar 62d is connected via a bus bar embedded in the bus bar assembly 93A to a bus bar 62e that is connected to other devices, and the bus bar 64d is integrally connected via a bus bar embedded in the bus bar assembly 60A to a bus bar 64e that is connected to other devices.

Like the soft-switching converter 100 of the example embodiment described above, the soft-switching converter 100A of this first modified example is also able to be made more compact.

Incidentally, although not shown, when forming a two-phase drive system soft-switching converter, the main reactor 10c, the main reactor terminal block 20c, the auxiliary reactor 30c, and the auxiliary reactor terminal block 40c and the like of the soft-switching converter 100 according to the example embodiment described above may be omitted as appropriate.

### B2. Second Modified Example

In the example embodiment described above, the input terminal 22ia and the output terminal 22oa of the main reactor terminal block 20a, for example, are sterically arranged on two levels, as shown in FIG. 3, but the invention is not limited to this. The input terminal 22ia and the output terminal 22oa of the main reactor terminal block 20a may also be arranged lined up on the same plane.

### B3. Third Modified Example

In the example embodiment described above, the auxiliary reactor terminal block 40a is arranged stacked on top of the auxiliary reactor 30a, for example, but the invention is not limited to this. For example, the auxiliary reactor terminal block 40a and the auxiliary reactor 30a may also be arranged lined up on the same plane.

Also, the positions in which the input terminal 42ia and the output terminal 42oa of the auxiliary reactor terminal block 40a are arranged may be switched, the positions in which the input terminal 42ib and the output terminal 42ob of the auxiliary reactor terminal block 40b are arranged may be switched, and the positions in which the input terminal 42ic and the output terminal 42oc of the auxiliary reactor terminal block 40c are arranged may be switched.

### B4. Fourth Modified Example

In the example embodiment described above, the current sensor 50a measures the current that flows to both of the main reactors 10a and 10b. Alternatively, however, a current sensor that measures the current that flows to the main reactor 10a and a current sensor that measures the current that flows to the main reactor 10b may be provided separately. This is also true for the current sensors 50a and 50b shown in FIG. 5.

Also, in the example embodiment described above, the main reactor terminal block 20a and the main reactor terminal block 20b that are arranged adjacent to one another are separate bodies, but they may also be integrated. This is also true for the main reactor terminal blocks 20c and 20d shown in FIG. 5.

Similarly, in the example embodiment described above, the auxiliary reactor terminal block 40b and the auxiliary reactor terminal block 40c that are arranged adjacent to one another are separate bodies, but they may also be integrated.

### B5. Fifth Modified Example

In the example embodiment described above, the bus bars 62a, 62b, and 62c of the bus bar assembly 60 are all connected, via the bus bar that is embedded in the bus bar assembly 60, to the common bus bar 62e that is connected to other devices. Alternatively, however, bus bars that are connected to the other devices and correspond to the bus bars 62a, 62b, and 62c may also be provided separately. Also, the bus bars 64a, 64b, and 64c of the bus bar assembly 60 are all connected, via the bus bar that is embedded in the bus bar assembly 60, to the common bus bar 64e that is connected to other devices. Alternatively, however, bus bars that are connected to the other devices and correspond to the bus bars 64a, 64b, and 64c may also be provided separately. Incidentally, these may be provided in appropriate positions on the bus bar assembly 60.

### B6. Sixth Modified Example

In the example embodiment described above, the bus bar assembly 60 that integrally supports a plurality of bus bars is used, but the invention is not limited to this. A bus bar may also be connected separately to each terminal. However, using the bus bar assembly 60 prevents an electrical short between bus bars and facilitates the work of connecting the plurality of bus bars to the terminals.

### B7. Seventh Modified Example

In the example embodiment described above, the invention is applied to a soft-switching converter, but the invention may also be applied to another power converter. The invention may generally be applied to a power converter provided with a plurality of sets of one main reactor, one main reactor terminal block, and one auxiliary reactor.

1. A power converter comprising:
a main reactor;
a main reactor terminal block having a main reactor input terminal for inputting a current into the main reactor, and a main reactor output terminal for outputting a current from the main reactor; and
an auxiliary reactor that is electrically connected to the main reactor;
wherein the main reactor, the auxiliary reactor, and the main reactor terminal block are provided in a plurality of sets, and each of the plurality of main reactors and each of the plurality of main reactor terminal blocks are arranged on a first line, and each of the plurality of auxiliary reactors are arranged on a second line that is parallel to the first line.

2. The power converter according to claim 1, wherein the main reactor input terminal and the main reactor output terminal of the main reactor terminal block are arranged in different positions in a direction perpendicular to the mounting surface of the main reactor terminal block.

3. The power converter according to claim 1, further comprising an auxiliary reactor terminal block having an auxiliary reactor input terminal for inputting a current into the auxiliary reactor, and an auxiliary reactor output terminal for outputting a current from the auxiliary reactor,
wherein the auxiliary reactor terminal block is provided in plurality, and each of the auxiliary reactor terminal blocks is arranged in a position overlapping with a corresponding one of the auxiliary reactors in a direction perpendicular to the mounting surface of the auxiliary reactor.

4. The power converter according to claim 3, wherein each of the auxiliary reactor terminal blocks is arranged stacked on top of a corresponding one of the auxiliary reactors, and the heights of the auxiliary reactor terminal blocks that are stacked on the auxiliary reactors with respect to the mounting surface of the auxiliary reactor are substantially the same as the height of the main reactor.

5. The power converter according to claim 1, further comprising:
a plurality of current sensors that measure the current that flows to the plurality of main reactors, wherein each of the plurality of current sensors is arranged on a third line that is parallel to the first line and on the same side of the first line as the second line.

6. The power converter according to claim 5, further comprising:
a conductive member assembly that includes a first conductive member that is connected to each of the plurality of auxiliary reactor input terminals, a second conductive member that is connected to each of the plurality of auxiliary reactor output terminals, and a supporting member that supports the first conductive member and the second conductive member while providing insulation between the first conductive member and the second conductive member, wherein the conductive member assembly is provided extending parallel to the first line, the second line, and the third line.

7. A fuel cell vehicle comprising:
the power converter according to claim 1, wherein the power converter is arranged in a center console.

8. The fuel cell vehicle according to claim 7, wherein the power converter is a soft-switching converter.
